(19) United States
(12) Patent Application Publication
(10) Pub. No.: US 2026/0005064 A1
(43) Pub. Date: Jan. 1, 2026

(54) SUBSTRATE SUPPORT ASSEMBLY AND PLASMA PROCESSING DEVICE

(71) Applicant: Tokyo Electron Limited, Tokyo (JP)

(72) Inventor: Atsushi KAWABATA, Miyagi (JP)

(73) Assignee: Tokyo Electron Limited, Tokyo (JP)

(21) Appl. No.: 19/317,800

(22) Filed: Sep. 3, 2025

Related U.S. Application Data
(63) Continuation of application No. PCT/JP2024/008349, filed on Mar. 5, 2024.

(30) Foreign Application Priority Data
Mar. 14, 2023 (JP) 2023-039609

(51) Int. Cl. H01L 21/687

(52) U.S. Cl. CPC H01L 21/68785

(57) ABSTRACT

A substrate support assembly includes a base, a substrate support on the base, and a supply unit. The base includes a first channel and a second channel. The first channel is a channel for a first heat transfer medium. The second channel is a channel for a second heat transfer medium. The supply unit is connected to the second channel. The second channel extends between the first channel and the substrate support. The supply unit is connected to the second channel to supply the second heat transfer medium to the second channel. The second heat transfer medium is a liquid metal.

### CROSS-REFERENCE TO RELATED APPLICATIONS

This application is a continuation application of PCT Application No. PCT/JP2024/008349, filed on Mar. 5, 2024, which claims the benefit of priority from Japanese Patent Application No. 2023-039609, filed on Mar. 14, 2023. The entire contents of the above listed PCT and priority applications are incorporated herein by reference.

### BACKGROUND

### Field

Exemplary embodiments of the disclosure relate to a substrate support assembly and a plasma processing device.

A plasma processing device performs plasma processing of substrates. A plasma processing device described in Japanese Unexamined Patent Application Publication No. 2001-110885 includes a chamber and a clamp. The clamp clamps a substrate. A refrigerant channel is defined in the clamp. The refrigerant channel receives a refrigerant from a refrigerant inlet. The refrigerant supplied to the refrigerant channel is discharged through a refrigerant outlet.

### SUMMARY

A substrate support assembly according to one exemplary embodiment includes a base, a substrate support on the base, and a supply unit. The base includes a first channel and a second channel. The first channel is a channel for a first heat transfer medium. The second channel is a channel for a second heat transfer medium. The supply unit is connected to the second channel. The second channel extends between the first channel and the substrate support. The supply unit is connected to the second channel to supply the second heat transfer medium to the second channel. The second heat transfer medium is a liquid metal.

### BRIEF DESCRIPTION OF DRAWINGS

FIG. 1 is a diagram of a plasma processing system, illustrating an example structure.

FIG. 2 is a diagram of a capacitively coupled plasma processing device, illustrating an example structure.

FIG. 3 is a schematic diagram of a substrate support assembly according to one exemplary embodiment.

FIGS. 4A to 4C are diagrams each describing supply of a second heat transfer medium performed by a supply unit in one exemplary embodiment.

FIG. 5 is a flowchart of a temperature control method for a substrate support in one exemplary embodiment.

FIG. 6 is a cross-sectional view of a substrate support assembly according to another exemplary embodiment.

FIG. 7A is a cross-sectional view of a second channel in one exemplary embodiment, FIG. 7B is a cross-sectional view of a second channel in another exemplary embodiment, and FIG. 7C is a cross-sectional view of a second channel in still another exemplary embodiment.

### DETAILED DESCRIPTION

Exemplary embodiments will now be described in detail with reference to the drawings. In the drawings, like reference numerals denote like or corresponding components.

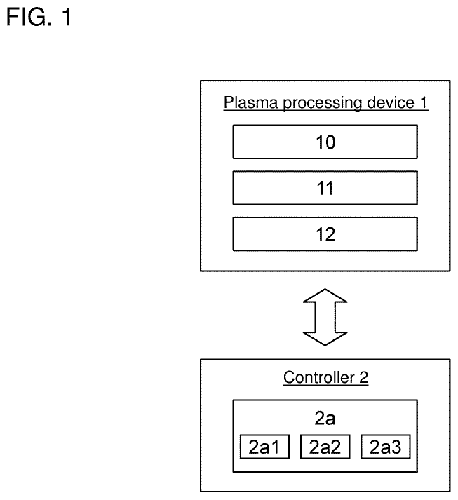

FIG. 1 is a diagram of a plasma processing system, illustrating an example structure. In one embodiment, the plasma processing system includes a plasma processing device 1 and a controller 2. The plasma processing system is an example of a substrate processing system. The plasma processing device 1 is an example of a substrate processing device. The plasma processing device 1 includes a plasma processing chamber 10, a substrate support assembly 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet connects to a gas supply 20 (described later). The gas outlet connects to an exhaust system 40 (described later). The substrate support assembly 11 is located in the plasma processing space and has a substrate support surface for supporting a substrate.

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave plasma (HWP), or surface wave plasma (SWP). Various plasma generators may be used, including an alternating current (AC) plasma generator and a direct current (DC) plasma generator. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing device 1 to perform various steps described in one or more embodiments of the disclosure. The controller 2 may control the components of the plasma processing device 1 to perform the various steps described herein. In one embodiment, some or all of the components of the controller 2 may be included in the plasma processing device 1. The controller 2 may include a processor 2a1, a storage 2a2, and a communication interface 2a3. The controller 2 is implemented by, for example, a computer 2a. The processor 2al may perform various control operations by reading a program from the storage 2a2 and executing the read program. This program may be prestored in the storage 2a2 or may be obtained through a medium as appropriate. The obtained program is stored into the storage 2a2, read from the storage 2a2, and executed by the processor 2a1. The medium may be one of various storage media readable by the computer 2a, or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing device 1 through a communication line such as a local area network (LAN).

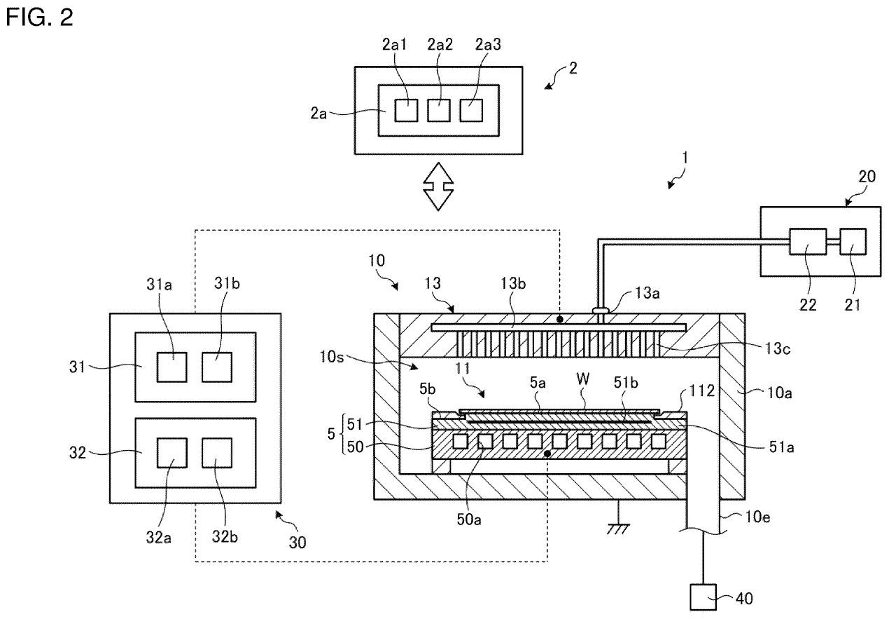

A capacitively coupled plasma processing device with an example structure will now be described as an example of the plasma processing device 1. FIG. 2 is a diagram of the capacitively coupled plasma processing device, illustrating an example structure.

The capacitively coupled plasma processing device 1 includes the plasma processing chamber 10, the gas supply 20, a power supply 30, and the exhaust system 40. The plasma processing device 1 includes the substrate support assembly 11 and a gas guide unit. The gas guide unit allows at least one process gas to be introduced into the plasma processing chamber 10. The gas guide unit includes a shower head 13. The substrate support assembly 11 is located in the plasma processing chamber 10. The shower head 13 is located above the substrate support assembly 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support assembly 11. The plasma processing chamber 10 is grounded. The shower head 13 and the substrate support assembly 11 are electrically insulated from a housing of the plasma processing chamber 10.

The substrate support assembly 11 includes a body 5 and a ring assembly 112. The body 5 includes a central area 5a for supporting a substrate W and an annular area 5b for supporting the ring assembly 112. A wafer is an example of the substrate W. The annular area 5b of the body 5 surrounds the central area 5a of the body 5 in a plan view. The substrate Wis placed on the central area 5a of the body 5. The ring assembly 112 is placed on the annular area 5b of the body 5 to surround the substrate W on the central area 5a of the body 5. Thus, the central area 5a is also referred to as a substrate support surface for supporting the substrate W. The annular area 5b is also referred to as a ring support surface for supporting the ring assembly 112.

In one embodiment, the body 5 includes a base 50 and a substrate support 51. The substrate support 51 is, for example, an electrostatic chuck (ESC). The base 50 includes a conductive member. The conductive member in the base 50 may serve as a lower electrode. The substrate support 51 is located on the base 50. The substrate support 51 includes a ceramic member 51a and an electrostatic electrode 51b located in the ceramic member 51a. The ceramic member 51a includes the central area 5a. In one embodiment, the ceramic member 51a also includes the annular area 5b. The annular area 5b may be included in another member surrounding the substrate support 51, such as an annular ESC or an annular insulating member. In this case, the ring assembly 112 may be placed on either the annular ESC or the annular insulating member, or may be placed on both the substrate support 51 and the annular insulating member. At least one RF/DC electrode coupled to an RF power supply 31 or a DC power supply 32, or both (described later) may be located in the ceramic member 51a. In this case, at least one RF/DC electrode serves as a lower electrode. When a bias RF signal or a DC signal, or both (described later) are provided to at least one RF/DC electrode, the RF/DC electrode is also referred to as a bias electrode. The conductive member in the base 50 and at least one RF/DC electrode may serve as multiple lower electrodes. The electrostatic electrode 51b may also serve as a lower electrode. Thus, the substrate support assembly 11 includes at least one lower electrode.

The ring assembly 112 includes one or more annular members. In one embodiment, one or more annular members include one or more edge rings and at least one cover ring. The edge rings are formed from a conductive material or an insulating material. The cover ring is formed from an insulating material.

The shower head 13 introduces at least one process gas from the gas supply 20 into the plasma processing space 10s. The shower head 13 includes at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas guide unit may include one or more side gas injectors (SGIs) installed in one or more openings in the side wall 10a.

The gas supply 20 may include at least one gas source 21 and at least one flow controller 22. In one embodiment, the gas supply 20 supplies at least one process gas from each gas source 21 to the shower head 13 through the corresponding flow controller 22. Each flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated one or more source RF signals are provided to at least one lower electrode or at least one upper electrode, or both.

The second RF generator 31b is coupled to at least one lower electrode through at least one impedance matching circuit and generates a bias RF signal (bias RF power). The bias RF signal may have a frequency that is the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode or at least one upper electrode, or both. The voltage pulses may have a rectangular, trapezoidal, triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may also include one or more positive voltage pulses and one or more negative voltage pulses within one cycle. The power supply 30 may include the first DC generator 32a and the second DC generator 32b in addition to the RF power supply 31. The first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

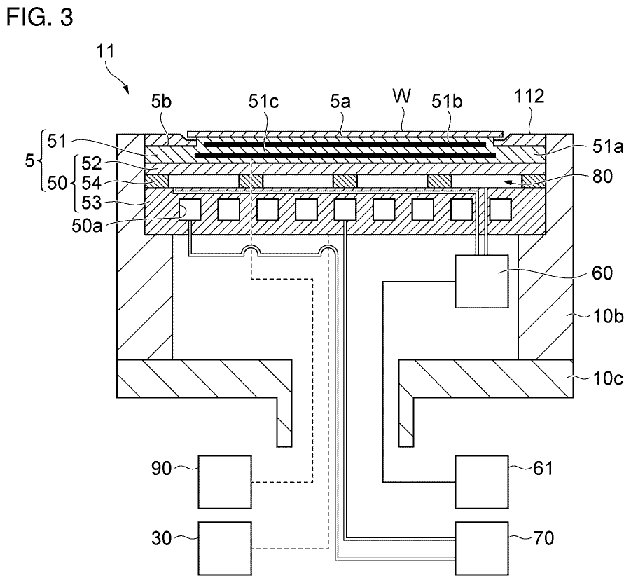

FIG. 3 is a schematic diagram of the substrate support assembly according to one exemplary embodiment. As described above, the body 5 in the substrate support assembly 11 includes the base 50 and the substrate support 51 on the base 50. The substrate support 51 is located on the base 50. As shown in FIG. 3, the body 5 in the substrate support assembly 11 may be supported by an insulating member 10b in the chamber 10. The insulating member 10b is located on a bottom 10c of the chamber 10.

The base 50 includes a first channel 50a and a second channel 80. The first channel 50a is a channel for a first heat transfer medium. The first channel 50a is defined in, for example, the base 50. The first heat transfer medium may be, for example, a refrigerant such as brine or gas. The substrate support assembly 11 may further include a supply unit 70. The supply unit 70 is connected to the first channel 50a to supply the first heat transfer medium to the first channel 50a.

The second channel 80 is a channel for a second heat transfer medium. The second heat transfer medium is a liquid metal. In one embodiment, the liquid metal may be a metal or a eutectic alloy with a melting point lower than or equal to −10° C. and a thermal conductivity higher than or equal to 5 W/mK under normal (atmospheric) pressure. The melting point of the liquid metal under normal (atmospheric) pressure may be lower than or equal to −15° C. The liquid metal is, for example, a Ga—In—Sn alloy. In the Ga—In—Sn alloy, the concentration of Ga may be 62 mass %, the concentration of In may be 25 mass %, and the concentration of Sn may be 13 mass %. The Ga—In—Sn alloy may be, for example, Galinstan (registered trademark).

The second channel 80 is separate from the first channel 50a. The second channel 80 extends between the first channel 50a and the substrate support 51. The substrate support assembly 11 further includes a supply unit 60. The supply unit 60 is connected to the second channel 80 to supply the second heat transfer medium to the second channel 80. In the example in FIG. 3, the supply unit 60 is located between the bottom 10c and the base 50 in the chamber 10. However, the supply unit 60 may be located outside the chamber 10. The supply unit 60 is insulated from the chamber 10.

In one embodiment, the plasma processing device 1 may further include at least one heater 51c in the substrate support 51 and a heater controller 90. The heater 51c is located in the substrate support 51. The heater 51c is located in, for example, the ceramic member 51a in the substrate support 51. The heater controller 90 supplies power to the heater 51c. The substrate support assembly 11 may include a temperature control module that adjusts the temperature of at least one of the substrate support 51, the ring assembly 112, or the substrate W to a target temperature. The temperature control module may include the heater 51c, the heater controller 90, the first channel 50a, the second channel 80, the supply unit 60, the supply unit 70, or a combination of these. The substrate support assembly 11 may include a heat transfer gas supply to supply a heat transfer gas to a space between the back surface of the substrate W and the central area 5a.

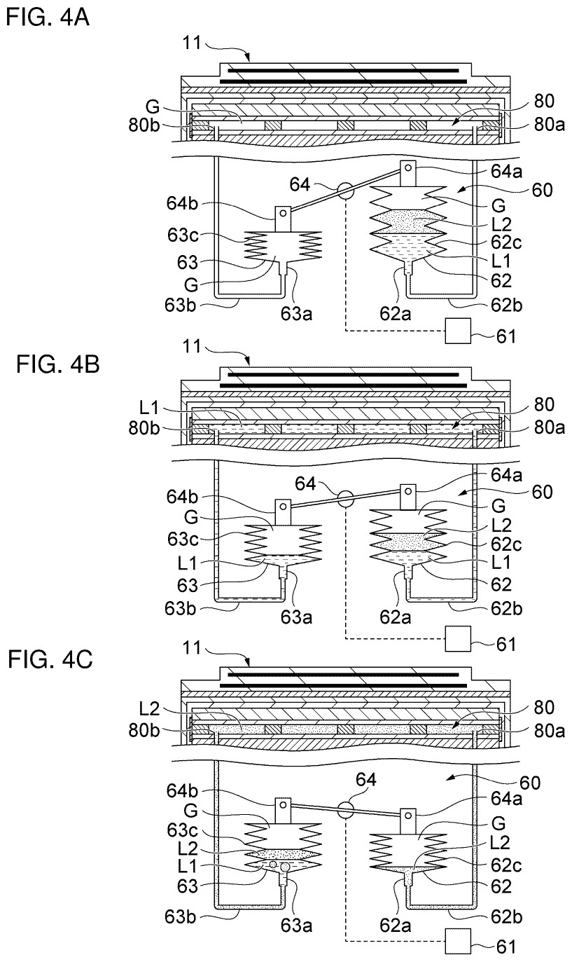

FIGS. 4A to 4C are diagrams each describing supply of the second heat transfer medium performed by the supply unit in one exemplary embodiment. In one embodiment, as shown in FIGS. 4A to 4C, the supply unit 60 may include a first container 62, a second container 63, and a pressure controller 61. The first container 62 is connected to a first end 80a of the second channel 80. The second container 63 is connected to a second end 80b of the second channel 80. The second end 80b is an end of the second channel 80 opposite to the first end 80a. The supply unit 60 is controlled by, for example, the controller 2.

In one embodiment, the supply unit 60 may selectively supply one of multiple heat transfer media including the second heat transfer medium to the second channel 80. The first container 62 and the second container 63 each store multiple heat transfer media inside. The first container 62 and the second container 63 may be formed from a nonmetal material. The first container 62 and the second container 63 are formed from, for example, a resin.

In one embodiment, the multiple heat transfer media may have different thermal conductivities. The heat transfer media may have different specific gravities. The heat transfer media may further include a liquid different from a liquid metal that is the second heat transfer medium. The heat transfer media may further include a gas. The different liquid may be a liquid that does not chemically react with the liquid metal and is moisture-free. The different liquid may have a lower melting point than the liquid metal. The different liquid may have a thermal conductivity lower than or equal to the thermal conductivity of the liquid metal and higher than or equal to the thermal conductivity of the gas. In the examples shown in FIGS. 4A to 4C, the heat transfer media include a liquid metal L1 that is the second heat transfer medium, silicone oil L2 that is the liquid different from the liquid metal L1, and nitrogen G that is the gas. The liquid different from the liquid metal L1 may be absolute alcohol or a fluorine refrigerant liquid in place of the silicone oil L2. The gas may be a noble gas. The heat transfer media may include two or four types of heat transfer media.

The first container 62 may define a first opening 62a in its lower portion. The second container 63 may define a second opening 63a in its lower portion. The first opening 62a and the first end 80a are connected to each other with a first pipe 62b. The second opening 63a and the second end 80b are connected to each other with a second pipe 63b.

The pressure controller 61 may pressurize one of the first container 62 or the second container 63 and depressurize the other of the first container 62 or the second container 63. In one embodiment, each of the first container 62 and the second container 63 may include a bellows. Each of the first container 62 and the second container 63 has a volume adjustable with the bellows. More specifically, the first container 62 includes a bellows 62c. The first container 62 has a volume adjustable with the bellows 62c. The second container 63 includes a bellows 63c. The second container 63 has a volume adjustable with the bellows 63c.

The pressure controller 61 may include a drive 64. The drive 64 causes the bellows in one of the first container 62 or the second container 63 to contract and causes the bellows in the other of the first container 62 or the second container 63 to extend. This reduces the volume of one container and increases the volume of the other container. The drive 64 may include a drive unit 64a and a drive unit 64b. The drive unit 64a causes the bellows 62c to extend or contract. The drive unit 64b causes the bellows 63c to extend or contract. The drives 64a and 64b may have a seesaw mechanism with which the drive unit 64a and the drive unit 64b are connected across the fulcrum. In this case, when the drive unit 64b is raised in response to the drive unit 64a being lowered, the bellows 63c is extended in response to the bellows 62c being contracted. This reduces the volume of the first container 62 to pressurize the first container 62, and increases the volume of the second container 63 to depressurize the second container 63. When the drive unit 64b is lowered in response to the drive unit 64a being raised, the bellows 63c is contracted in response to the bellows 62c being extended. This increases the volume of the first container 62 to depressurize the first container 62, and reduces the volume of the second container 63 to pressurize the second container 63.

In the example in FIG. 4A, the first container 62 contains the liquid metal L1, the silicone oil L2, and the nitrogen G. The liquid metal L1, the silicone oil L2, and the nitrogen G are stored in this order from below in the first container 62 based on their specific gravities. The liquid metal L1 is stored below the silicone oil L2 and the nitrogen G in the first container 62. The second channel 80 is filled with the nitrogen G.

The drive unit 64a is further lowered, and the drive unit 64b is further raised in FIG. 4B than in FIG. 4A. As described above, when the drive unit 64b is raised in response to the drive unit 64a being lowered, the second container 63 is depressurized in response to the first container 62 being pressurized. The liquid metal L1 is thus supplied from the pressurized first container 62 to the second channel 80 through the first opening 62a and the first pipe 62b. The nitrogen G filing the second channel 80 is pushed by the supplied liquid metal L1 and stored into the depressurized second container 63. Thus, in the example shown in FIG. 4B, the second channel 80 is filled with the liquid metal L1 to equalize the pressures in the first container 62 and the second container 63. The silicone oil L2 and the nitrogen G remain in the first container 62. The silicone oil L2 and the nitrogen G are stored in this order from below in the first container 62 based on their specific gravities. The silicone oil L2 is stored below the nitrogen G in the first container 62.

The drive unit 64a is further lowered, and the drive unit 64b is further raised in FIG. 4C than in FIG. 4B. The silicone oil L2 is thus supplied from the pressurized first container 62 to the second channel 80 through the first opening 62a and the first pipe 62b. The liquid metal L1 filing the second channel 80 is pushed by the supplied silicone oil L2 and stored into the depressurized second container 63. Thus, in the example shown in FIG. 4C, the second channel 80 is filled with the silicone oil L2 to equalize the pressures in the first container 62 and the second container 63.

The drive 64 may further lower the drive unit 64a and further raise the drive unit 64b than in FIG. 4C. Thus, the nitrogen G is supplied from the pressurized first container 62 to the second channel 80 through the first opening 62a and the first pipe 62b. The silicone oil L2 filing the second channel 80 is pushed by the supplied nitrogen G and stored into the depressurized second container 63.

The pressure controller 61 may pressurize the second container 63 and depressurize the first container 62 to supply one of the liquid metal L1, the silicone oil L2, or the nitrogen G in the second container 63 from the second container 63 to the second channel 80.

In one embodiment, the controller 2 may control the supply unit 60 to discharge the liquid metal L1 from the second channel 80 in a first period T1. The controller 2 may control the supply unit 60 to supply the liquid metal L1 to the second channel 80 in a second period T2 different from the first period T1.

In one embodiment, the controller 2 may control the heater controller 90 to provide power to the heater 51c and control the supply unit 60 to discharge the liquid metal L1 from the second channel 80 in the first period T1. This reduces heat exchange between the base 50 and the substrate support 51 in the first period T1, efficiently heating the substrate W. The controller 2 may control the supply unit 60 to supply the liquid metal L1 to the second channel 80 in the second period T2. This facilitates heat exchange between the base 50 and the substrate support 51 in the second period T2, efficiently cooling the substrate W. The supply unit 70 may supply a refrigerant to the first channel 50a in the first period T1 and the second period T2. The supply unit 70 may supply a refrigerant to the first channel 50a in the second period T2 alone.

In one embodiment, the supply unit 60 may selectively supply one of multiple heat transfer media including the liquid metal L1 and the gas to the second channel 80. The gas may be the nitrogen G. The controller 2 may control the supply unit 60 to supply the nitrogen G to the second channel 80 in the first period T1.

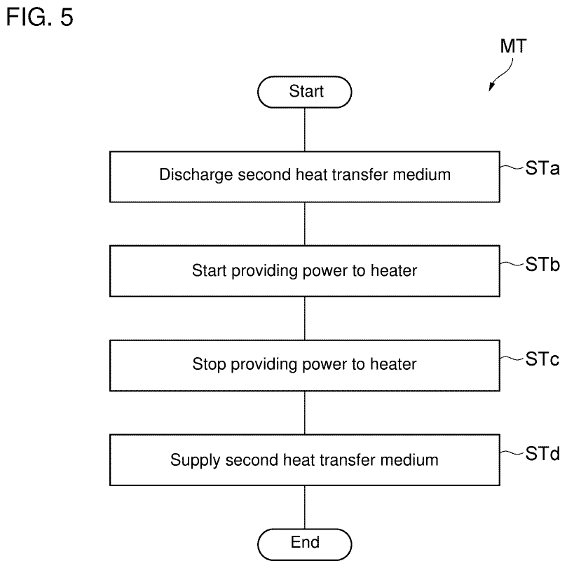

A temperature control method for the substrate support in one exemplary embodiment will now be described with reference to FIG. 5. FIG. 5 is a flowchart of the temperature control method for the substrate support in the exemplary embodiment. The temperature control method shown in FIG. 5 (hereafter referred to as a method MT) may be performed with the substrate W placed on the substrate support 51 in the chamber 10. The method MT may include performing plasma processing of the substrate W.

The method MT starts from step STa. In step STa, the liquid metal L1 is discharged from the second channel 80. In one embodiment, the gas may be supplied to the second channel 80 in step STa. The gas may be the nitrogen G. The liquid metal L1 in the second channel 80 may be pushed by the supplied nitrogen G and discharged from the second channel 80.

Step STb is performed in parallel with or after step STa. In step STb, the heater 51c starts being powered. Thus, the heater 51c generates heat to heat the substrate W on the substrate support 51. When the second channel 80 is not filled with the liquid metal L1 without the processing in step STa being performed, the method MT may start from step STb.

In step STc, the heater 51c stops being powered. This stops heat generation of the heater 51c.

Step STd is performed in parallel with or after step STc. In step STd, the liquid metal L1 is supplied to the second channel 80. In one embodiment, the nitrogen G may be discharged from the second channel 80 in step STd. The liquid metal L1 may be sucked into the second channel 80, from which the nitrogen G is discharged, to fill the second channel 80.

Steps STa and STb may be performed to heat the substrate W in the first period T1. Steps STc and STd may be performed to cool the substrate W in the second period T2. Steps STc and STd may be performed after or before steps STa and STb.

As described above, the base 50 in the substrate support assembly 11 defines the first channel 50a and the second channel 80 inside. The second channel 80 is located closer to the substrate support 51 than the first channel 50a. The liquid metal L1 supplied to the second channel 80 causes high heat exchange efficiency between the first heat transfer medium and the substrate support 51. In this state, the temperature of the substrate support 51 can be controlled to be closer to the temperature of the first heat transfer medium. No liquid metal L1 supplied to the second channel 80 causes low heat exchange efficiency between the first heat transfer medium and the substrate support 51. In this state, the temperature of the substrate support 51 can be controlled to be far from the temperature of the first heat transfer medium. The substrate support 51 in the substrate support assembly 11 thus has high temperature controllability.

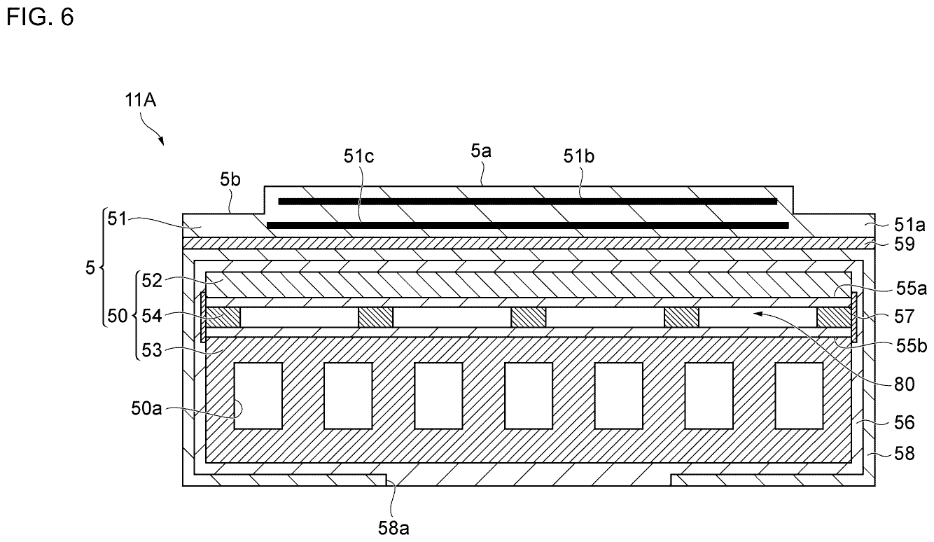

A substrate support assembly according to another exemplary embodiment will now be described with reference to FIG. 6. FIG. 6 is a cross-sectional view of the substrate support assembly according to the other exemplary embodiment. A substrate support assembly 11A shown in FIG. 6 may replace the substrate support assembly 11 in the plasma processing device 1. The substrate support assembly 11A will now be described focusing on its differences from the substrate support assembly 11.

The base 50 in the substrate support assembly 11A may include a first base 52, a second base 53, and a support member 54. The first base 52 supports the substrate support 51 on the first base 52. The second base 53 includes the first channel 50a inside. The support member 54 is located between the first base 52 and the second base 53 to support the first base 52. The support member 54 defines the second channel 80 between the first base 52 and the second base 53.

In one embodiment, the material of the support member 54 may have a lower thermal conductivity than the material of the base 50. The material of the support member 54 may have a thermal conductivity lower than or equal to 1 W/mK. The support member 54 is formed from, for example, at least one material selected from the group consisting of a resin material, a ceramic material, and a composite material. The support member 54 may be formed from a fluororesin. The support member may be formed from at least one material selected from the group consisting of polytetrafluoroethylene, polyetherether ketone, and porous ceramic. The support member 54 may be formed from a composite material. The composite material is a material including two or more different materials being combined. For example, the composite material is a material including two or more materials selected from the group consisting of a resin, a metal, glass, and carbon being combined.

In one embodiment, the substrate support assembly 11A may further include a first protective layer 55a on the first base 52 and a second protective layer 55b on the second base 53. The first protective layer 55a is located on the surface of the first base 52. The first protective layer 55a is thus located between the second channel 80 and the first base 52 and between the support member 54 and the first base 52. The second protective layer 55b is located on the surface of the second base 53. The second protective layer 55b is thus located between the second channel 80 and the second base 53 and between the support member 54 and the second base 53. In this case, the second channel 80 may be defined by the first protective layer 55a, the second protective layer 55b, and the support member 54. Each of the first protective layer 55a and the second protective layer 55b may have a higher thermal conductivity than the support member 54. For example, each of the material of the first protective layer 55a and the material of the second protective layer 55b has a higher thermal conductivity than the material of the support member 54.

In one embodiment, each of the first protective layer 55a and the second protective layer 55b may be formed from at least one material selected from the group consisting of graphite, carbon nanotubes, and columnar aluminum nitride. Each of the first protective layer 55a and the second protective layer 55b may be formed from a composite material mainly containing carbon nanotubes or columnar aluminum nitride. Each of the first protective layer 55a and the second protective layer 55b may be formed from a material with a higher thermal conductivity in a horizontal direction than in a vertical direction. The vertical direction is a thickness direction of each of the first protective layer 55a and the second protective layer 55b. The horizontal direction is perpendicular to the thickness direction of each of the first protective layer 55a and the second protective layer 55b. Each of the first protective layer 55a and the second protective layer 55b has a thermal conductivity in the horizontal direction, for example, greater than or equal to 10 times the thermal conductivity in the vertical direction. Each of the first protective layer 55a and the second protective layer 55b may have a higher thermal conductivity in the horizontal direction than the first base 52 and the second base 53. Graphite has a layered structure. The thermal conductivity is higher in a direction (horizontal direction) along the layers of the graphite than in a direction (vertical or thickness direction) perpendicular to the layers of the graphite.

In one embodiment, the first protective layer 55a and the second protective layer 55b may be conductive. The first protective layer 55a and the second protective layer 55b may be formed from graphite as a conductive material.

In one embodiment, the first base 52 and the second base 53 may be formed from at least one material selected from the group consisting of SiC, a metal composite material, and a metal. The metal may be stainless steel, titanium, or molybdenum. The first base 52 and the second base 53 may be formed from a metal that is less likely to be embrittled by the liquid metal L1. The first base 52 and the second base 53 may be formed from a nonmetal material. The first base 52 and the second base 53 may be formed from SiC. SiC is nonmetal and nonconductive. The metal composite material is a composite material mainly containing a metal.

In one embodiment, the substrate support assembly 11A may further include a conductive layer 56. The conductive layer 56 covers the surface of the base 50. The conductive layer 56 is conductive. The conductive layer 56 is formed from, for example, aluminum thermally sprayed on the surface of the base 50. The conductive layer 56 may cover the upper surface, the side surface, and the bottom surface of the base 50. The conductive layer 56 is electrically connected to the first protective layer 55a and the second protective layer 55b. The conductive layer 56 may be electrically coupled to the power supply 30.

The substrate support assembly 11A may further include a conductive member 57.

The conductive member 57 is electrically connected to the first protective layer 55a and the second protective layer 55b. The conductive member 57 is, for example, copper tape. The conductive layer 56 covers the conductive member 57. The conductive member 57 is electrically connected to the conductive layer 56.

The substrate support assembly 11A may further include an insulating layer 58. The insulating layer 58 covers the conductive layer 56. The insulating layer 58 is insulating. The insulating layer 58 is formed from, for example, yttrium oxide thermally sprayed on the conductive layer 56. The insulating layer 58 is formed from, for example, yttrium oxide. The insulating layer 58 may be formed from another insulating material, such as aluminum oxide or yttrium fluoride. The insulating layer 58 may define an opening 58a in the lower surface of the base 50. A part of the conductive layer 56 is exposed through the opening 58a. The conductive layer 56 may be electrically coupled to the power supply 30 at the part of the conductive layer 56 exposed through the opening 58a.

In the substrate support assembly 11A, the liquid metal L1 supplied to the second channel 80, the first protective layer 55a, the second protective layer 55b, and the conductive layer 56 are electrically connected to one another to have the same potential. The substrate support assembly 11A can thus reduce abnormal discharge resulting from a potential difference.

In one embodiment, the substrate support assembly 11A may further include a bonding layer 59 between the base 50 and the substrate support 51. The bonding layer 59 is located between the base 50 and the substrate support 51. The bonding layer 59 bonds the base 50 and the substrate support 51 to each other. The bonding layer 59 may be located between the first base 52 and the substrate support 51. The bonding layer 59 may bond the first base 52 and the substrate support 51 to each other. The bonding layer 59 is formed from a material with a thermal conductivity of 2 to 20 W/mK inclusive. For example, the bonding layer 59 may be an adhesive sheet formed from an organic adhesive containing a thermal conductive filler. The bonding layer 59 may absorb distortion between the base 50 and the substrate support 51. The distortion results from a difference between the thermal expansion coefficients of the base 50 and the substrate support 51. In one embodiment, the bonding layer 59 may have a thickness of 25 to 300 μm inclusive.

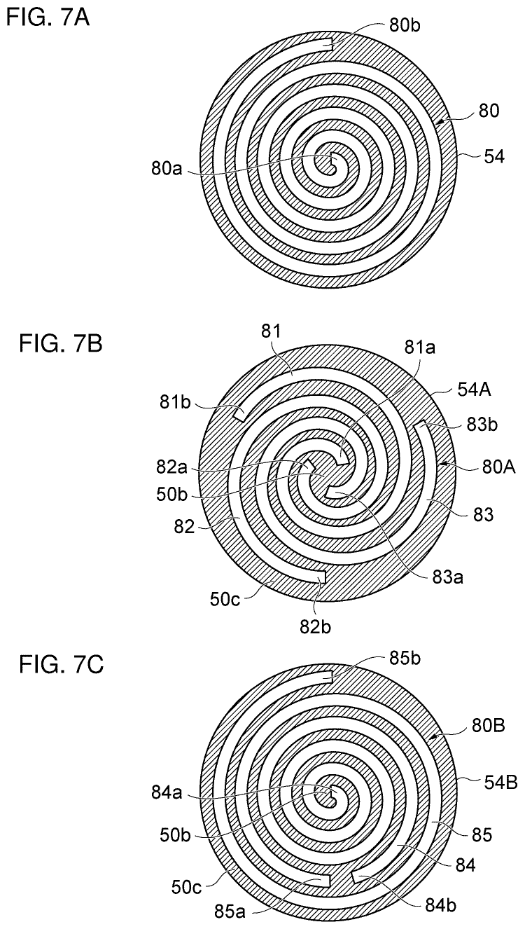

The second channel in various exemplary embodiments will now be described. FIG. 7A is a cross-sectional view of the second channel in one exemplary embodiment. In FIG. 7A, the second channel 80 and the support member 54 are viewed in the vertical direction. The second channel 80 may include at least one channel. The at least one channel spirally extends between the center of the base 50 and the peripheral edge of the base 50. As shown in FIG. 7A, the second channel 80 may include a single channel. The second channel 80 shown in FIG. 7A, or specifically, the single channel, spirally extends between the center of the base 50 and the peripheral edge of the base 50. The second channel 80 may spirally extend from the first end 80a to the second end 80b. The first end 80a is located at, for example, the center of the base 50. The second end 80b is located at, for example, the peripheral edge of the base 50.

FIG. 7B is a cross-sectional view of a second channel in another exemplary embodiment. In the example in FIG. 7B, a second channel 80A and a support member 54A are viewed in the vertical direction. In one embodiment, the base 50 may include a central area 50b and a peripheral area 50c. The central area 50b includes the center of the base 50. The central area 50b includes, for example, the substrate support surface (central area 5a) of the body 5. The peripheral area 50c surrounds the central area 50b. The peripheral area 50c includes, for example, the ring support surface (annular area 5b) of the body 5. The second channel 80 may include multiple channels as at least one channel. Each of the multiple channels spirally extends across the central area 50b and the peripheral area 50c. Each of the multiple channels spirally extends from the first end in the central area 50b to the corresponding second end in the peripheral area 50c.

In the example in FIG. 7B, the second channel 80A includes a channel 81, a channel 82, and a channel 83. The channel 81 has a first end 81a located in the central area 50b and a second end 81b located in the peripheral area 50c. The channel 82 has a first end 82a located in the central area 50b and a second end 82b located in the peripheral area 50c. The channel 83 has a first end 83a located in the central area 50b and a second end 83b located in the peripheral area 50c. The channels 81, 82, and 83 respectively extend spirally from the first ends 81a, 82a, and 83a in the central area 50b to the second ends 81b, 82b, and 83b in the peripheral area 50c. In this case, the first container 62 may be connected to the first ends 81a, 82a, and 83a. The second container 63 may be connected to the second ends 81b, 82b, and 83b.

In the example in FIG. 7B, the liquid metal L1 can be supplied to each of the channels 81, 82, and 83 being the second channel 80A. The structure in which the liquid metal can be supplied to the multiple channels being the second channel as in the example in FIG. 7B increases both the rates of supplying the liquid metal L1 to the second channel and discharging the liquid metal L1 from the second channel.

FIG. 7C is a cross-sectional view of a second channel in still another exemplary embodiment. In the example in FIG. 7C, a second channel 80B and a support member 54B are viewed in the vertical direction. In one embodiment, the base 50 may include multiple areas including the central area 50b and the peripheral area 50c. The second channel 80B may include multiple channels as at least one channel. The multiple channels may be defined in the respective areas of the base 50. The multiple areas may further include one or more other areas between the central area 50b and the peripheral area 50c. The multiple channels may each be defined in the central area 50b, the peripheral area 50c, and the one or more other areas. More specifically, the second channel 80B includes a channel 84 and another channel 85 as at least one channel in the example in FIG. 7C. The channel 84 spirally extends in the central area 50b. The other channel 85 spirally extends in the peripheral area 50c.

The channel 84 may spirally extend from a first end 84a to a second end 84b. The first end 84a is located at, for example, the center of the central area 50b. The second end 84b is located at, for example, the outer edge of the central area 50b. The other channel 85 may spirally extend from a first end 85a to a second end 85b. The first end 85a is located at, for example, the inner edge of the peripheral area 50c. The second end 85b is located at, for example, the outer edge of the peripheral area 50c.

In the embodiment in which the multiple channels are defined in the respective areas of the base 50 as in the example in FIG. 7C, one or more supply units may be connected to the multiple channels to independently change the types of heat transfer media to be supplied to the multiple channels. In this case, the heat exchange efficiency between the first heat transfer medium and the substrate support 51 is independently controllable in each of the multiple areas of the base 50. Thus, the temperatures of the multiple areas of the substrate W located on the respective areas of the base 50 are controllable independently.

Although various exemplary embodiments have been described above, the embodiments are not restrictive, and various additions, omissions, substitutions, and changes may be made. The components in the different embodiments may be combined to form another embodiment.

For example, the first container 62 may not include the bellows 62c. The second container 63 may not include the bellows 63c. Each of the first container 62 and the second container 63 may include a cylinder and a piston. The cylinder has a volume adjustable with the piston. The drive 64 may operate the pistons in the first container 62 and the second container 63. The pressure controller 61 may not include the drive 64. For example, the pressure controller 61 may be an air pump. The air pump may directly pressurize or depressurize the first container 62 and the second container 63 by injecting the nitrogen G into the first container 62 and the second container 63 or by discharging the nitrogen G from the first container 62 and the second container 63.

In still another exemplary embodiment, a base may not include the first channel 50a. A substrate support assembly according to the still other exemplary embodiment includes a base including the second channel 80, the substrate support 51 on the base, a supply unit, and a heat transfer gas supply. The supply unit is connected to the second channel 80. The supply unit can supply heat transfer media including the liquid metal L1 to the second channel 80, and can collect the heat transfer media from the second channel 80. The heat transfer gas supply supplies a heat transfer gas to a space between the surface of the substrate support 51 and the substrate W supported by the substrate support 51.

Various exemplary embodiments E1 to E30 included in the disclosure will now be described.

### E1

A substrate support assembly, comprising:
a base including a first channel for a first heat transfer medium and a second channel for a second heat transfer medium;
a substrate support on the base; and
a supply connected to the second channel and configured to supply the second heat transfer medium, which is a liquid metal, to the second channel, wherein the second channel extends between the first channel and the substrate support.

### E2

The substrate support assembly according to claim 1, wherein
the liquid metal has a melting point lower than or equal to −10° C. and a thermal conductivity higher than or equal to 5 W/mK under atmospheric pressure.

### E3

The substrate support assembly according to E1 or E2, wherein
the supply is configured to selectively supply one of a plurality of heat transfer media including the second heat transfer medium to the second channel.

### E4

The substrate support assembly according to E3, wherein the plurality of heat transfer media have different thermal conductivities.

### E5

The substrate support assembly according to E3 or E4, wherein the plurality of heat transfer media have different specific gravities.

### E6

The substrate support assembly according to any one of E3 to E5, wherein
the plurality of heat transfer media include a liquid different from the second heat transfer medium being the liquid metal.

### E7

The substrate support assembly according to any one of E3 to E6, wherein the plurality of heat transfer media include a gas.

### E8

the supply includes
a first container connected to a first end of the second channel and configured to store the plurality of heat transfer media inside,
a second container connected to a second end opposite to the first end of the second channel and configured to store the plurality of heat transfer media inside, and
a pressure controller configured to pressurize one of the first container or the second container and depressurize the other of the first container or the second container.

### E9

The substrate support assembly according to claim 8, wherein
each of the first container and the second container includes a bellows, and each of the first container and the second container has a volume adjustable with the bellows, and
the pressure controller includes a drive configured to cause the bellows in one of the first container or the second container to contract to reduce the volume of the one container and cause the bellows in the other of the first container or the second container to extend to increase the volume of the other container.

### E10

The substrate support assembly according to any one of E1 to E9, wherein
the base includes
   a first base on which the substrate support is located,
   a second base including the first channel inside, and
   a support between the first base and the second base and configured to support the first base and define the second channel between the first base and the second base.

### E11

The substrate support assembly according to E10, wherein
the support comprises a material with a lower thermal conductivity than a material of the base.

### E12

The substrate support assembly according to E10 or E11, wherein
the support comprises a material with a thermal conductivity lower than or equal to 1 W/mK.

### E13

The substrate support assembly according to any one of E10 to E12, wherein
the support comprises a fluororesin.

### E14

The substrate support assembly according to any one of E10 to E12, wherein
the support comprises at least one material selected from the group consisting of a resin material, a ceramic material, and a composite material.

### E15

The substrate support assembly according to any one of E10 to E14, wherein
the base further includes
   a first protective layer on the first base, the first protective layer being between the second channel and the first base and between the support and the first base, and
   a second protective layer on the second base, the second protective layer being between
the second channel and the second base and between the support and the second base,
the second channel is defined by the first protective layer, the second protective layer, and the support, and
each of the first protective layer and the second protective layer has a higher thermal conductivity than the support.

### E16

The substrate support assembly according to E15, wherein
each of the first base and the second base comprises a nonmetal material.

### E17

The substrate support assembly according to E16, wherein
each of the first protective layer and the second protective layer is conductive.

### E18

The substrate support assembly according to E17, further comprising:
a conductive layer covering a surface of the base, the conductive layer being electrically connected to the first protective layer and the second protective layer.

### E19

The substrate support assembly according to E15, wherein
each of the first base and the second base comprises at least one material selected from the group consisting of SiC, a metal composite material, and a metal.

### E20

The substrate support assembly according to E15, wherein
each of the first protective layer and the second protective layer comprises at least one material selected from the group consisting of graphite, carbon nanotubes, and columnar aluminum nitride.

### E21

The substrate support assembly according to any one of E1 to E20, further comprising:
a bonding layer between the base and the substrate support, the bonding layer bonding the base and the substrate support to each other, the bonding layer comprising a material with a thermal conductivity of 2 to 20 W/mK inclusive.

### E22

The substrate support assembly according to E21, wherein
the bonding layer has a thickness of 25 to 300 μm inclusive.

### E23

The substrate support assembly according to any one of E1 to E22, wherein
the second channel includes at least one channel spirally extending between a center of the base and a peripheral edge of the base.

### E24

The substrate support assembly according to E23, wherein
the base includes a central area including the center of the base and a peripheral area surrounding the central area, and
the second channel includes, as the at least one channel, a plurality of channels spirally extending across the central area and the peripheral area.

### E25

The substrate support assembly according to E23, wherein
the base includes a central area including the center of the base and a peripheral area surrounding the central area, and
the second channel includes, as the at least one channel, a channel spirally extending in the central area and another channel spirally extending in the peripheral area.

### E26

A substrate support assembly, comprising:
a base including a channel;
a substrate support on the base;
a supply connected to the channel, the supply being configured to supply a heat transfer medium including a liquid metal to the channel and to collect the heat transfer medium from the channel; and
a heat transfer gas supply configured to supply a heat transfer gas to a space between a surface of the substrate support and a substrate supported by the substrate support.

### E27

A plasma processing device, comprising:
a chamber; and
the substrate support assembly according to any one of E1 to E26,
   wherein the base and the substrate support are in the chamber.

### E28

The plasma processing device according to E27, further comprising:
a controller configured to
   control the supply to discharge the second heat transfer medium from the second channel in a first period, and
   control the supply to supply the second heat transfer medium to the second channel in a second period different from the first period.

### E29

The plasma processing device according to E28, further comprising:
a heater in the substrate support; and
a heater controller configured to provide power to the heater,
wherein the controller is configured to control the heater controller to provide power to the heater in a period during which a substrate is heated, and control the supply to discharge the second heat transfer medium from the second channel, and
the controller is configured to control the supply to supply the second heat transfer medium to the second channel in a period during which the substrate is cooled.

### E30

The plasma processing device according to E29, wherein
the supply is configured to selectively supply one of a plurality of heat transfer media including the second heat transfer medium and a gas to the second channel, and
the controller is configured to control the supply to supply the gas to the second channel in the period during which the substrate is heated.

Various exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

1. A substrate support assembly, comprising:
a base including a first channel for a first heat transfer medium and a second channel for a second heat transfer medium;
a substrate support on the base; and
a supply connected to the second channel and configured to supply the second heat transfer medium, which is a liquid metal, to the second channel,
wherein the second channel extends between the first channel and the substrate support.

2. The substrate support assembly according to claim 1, wherein
the liquid metal has a melting point lower than or equal to −10° C. and a thermal conductivity higher than or equal to 5 W/mK under atmospheric pressure.

3. The substrate support assembly according to claim 1, wherein
the supply is configured to selectively supply one of a plurality of heat transfer media including the second heat transfer medium to the second channel.

4. The substrate support assembly according to claim 3, wherein
the plurality of heat transfer media have different thermal conductivities.

5. The substrate support assembly according to claim 4, wherein
the plurality of heat transfer media have different specific gravities.

6. The substrate support assembly according to claim 5, wherein
the plurality of heat transfer media include a liquid different from the second heat transfer medium being the liquid metal.

7. The substrate support assembly according to claim 5, wherein
the plurality of heat transfer media include a gas.

8. The substrate support assembly according to claim 3, wherein
the supply includes
a first container connected to a first end of the second channel and configured to store the plurality of heat transfer media inside,
a second container connected to a second end opposite to the first end of the second channel and configured to store the plurality of heat transfer media inside, and
a pressure controller configured to pressurize one of the first container or the second container and depressurize the other of the first container or the second container.

9. The substrate support assembly according to claim 8, wherein
each of the first container and the second container includes a bellows, and each of the first container and the second container has a volume adjustable with the bellows, and
the pressure controller includes a drive configured to cause the bellows in one of the first container or the second container to contract to reduce the volume of the one container and cause the bellows in the other of the first container or the second container to extend to increase the volume of the other container.

10. The substrate support assembly according to claim 1, wherein
the base includes
a first base on which the substrate support is located,
a second base including the first channel inside, and
a support between the first base and the second base and configured to support the first base and define the second channel between the first base and the second base.

11. The substrate support assembly according to claim 10, wherein
the support comprises a material with a lower thermal conductivity than a material of the base.

12. The substrate support assembly according to claim 10, wherein
the support comprises a material with a thermal conductivity lower than or equal to 1 W/mK.

13. The substrate support assembly according to claim 10, wherein
the support comprises a fluororesin.

14. The substrate support assembly according to claim 10, wherein
the support comprises at least one material selected from the group consisting of a resin material, a ceramic material, and a composite material.

15. The substrate support assembly according to claim 10, wherein
the base further includes
a first protective layer on the first base, the first protective layer being between the second channel and the first base and between the support and the first base, and
a second protective layer on the second base, the second protective layer being between the second channel and the second base and between the support and the second base,
the second channel is defined by the first protective layer, the second protective layer, and the support, and
each of the first protective layer and the second protective layer has a higher thermal conductivity than the support.

16. The substrate support assembly according to claim 15, wherein
each of the first base and the second base comprises a nonmetal material.

17. The substrate support assembly according to claim 16, wherein
each of the first protective layer and the second protective layer is conductive.

18. The substrate support assembly according to claim 17, further comprising:
a conductive layer covering a surface of the base, the conductive layer being electrically connected to the first protective layer and the second protective layer.

19. The substrate support assembly according to claim 15, wherein
each of the first base and the second base comprises at least one material selected from the group consisting of SiC, a metal composite material, and a metal.

20. The substrate support assembly according to claim 15, wherein
each of the first protective layer and the second protective layer comprises at least one material selected from the group consisting of graphite, carbon nanotubes, and columnar aluminum nitride.
